(19) United States
(12) Patent Application Publication
(10) Pub. No.: US 2001/0036751 A1
(43) Pub. Date: Nov. 1, 2001

(54) Method for forming a thin oxide layer using wet oxidation

(75) Inventors: Chan-Sik Park, Suwon-city (KR); Sang-Woon Kim, Suwon-city (KR); Chung-Hwan Kwon, Osan-city (KR); Sae-Hyoung Ryu, Yongin-city (KR)

Correspondence Address: MARGER JOHNSON & MCCOLLOM PC, 1030 SW MORRISON STREET, PORTLAND, OR, 97205, US

(73) Assignee: Samsung Electronics Co., Ltd., Suwon-City (KR)

(21) Appl. No.: 09/874,267

(22) Filed: Jun. 4, 2001

Related U.S. Application Data
(62) Division of application No. 09/098,556, filed on Jun. 16, 1998.

(30) Foreign Application Priority Data
Jun. 16, 1997 (KR) 97-24829

(51) Int. Cl. H01L 21/31

(52) U.S. Cl. 438/773

(57) ABSTRACT

A process for forming oxide layer on a wafer, which comprises a wet oxidation step using a pyrogenic steam as an oxidizing agent. The present invention comprises a flowing of an inert gas throughout the process including the wet oxidation step. The process allows an easy control of the oxide layer growth rate and oxide layer thickness, a formation of a more uniform oxide layer, and an improvement in the quality of the oxide layer.

### BACKGROUND OF THE INVENTION

1. Field of the Invention

The present invention relates generally to a process for forming an oxide layer or oxide film on a semiconductor substrate or wafer. More particularly, the present invention relates to a process for forming an oxide layer on a semiconductor substrate by flowing an inert gas during wet oxidation, thereby allowing a control of the thickness and the growth time of the oxide layer.

2. Description of the Related Arts

The current need for high integrity semiconductor integrated circuit (IC) device requires reducing the size of the chip on which it is formed, making the wafer fabrication more complicated. Moreover, in an effort to increase production output wafer size and wafer manufacturing equipment dimensions have grown. In particular, the diameter of the furnace, where an oxide layer is formed and grown on the wafer, has increased, making it more difficult to form a thinner and a higher quality oxide layer.

In the semiconductor industry, silicon dioxide (SiO₂) layer (referred to as ‘oxide layer’) is used in a variety of applications. For example, it is used as field oxide to electrically insulate one device from another device; it is used as gate oxide on an MOS device; or it is used as passivation layer to insulate one metal wire pattern from another metal or for scratch protection from exterior environments.

SiO₂ can be grown in a dry process utilizing oxygen (O₂), or in a wet process using steam as the oxidizing agent. A wet process is typically employed to form a thick oxide layer since it allows a faster growth of the layer. However, recently, a wet process is also employed to form a thin oxide layer having a thickness of about 300 Å or less, since it can assure an improvement of the quality of the oxide layer over that of a dry process.

The wet process and its features are described in detail in, for example, Silicon Processing For The VLSI Era, Vol. 1; U.S. Pat. No. 5,244,834 and U.S. Pat. No. 5,210,056.

The conventional wet process will be described with reference to FIG. 1 and FIG. 2 below.

FIG. 1 is a schematic diagram of a furnace (or heater) where a conventional wet oxidation process is performed; and FIG. 2 is a graph showing the kinds of gases and the range of temperatures employed for a wet oxidation process in relation to the lapse of time. Referring to FIG. 1, a wafer container 80 carrying wafers position for processing by a wet oxidation process is located within and sealed inside a furnace 100. The furnace 100 has a gas inlet 70 at its upper part, and the gas inlet 70 is connected to burner 50 via duct 60. The gas duct for supplying gases to the furnace 100 will be described in more detail below. Nitrogen, oxygen, and hydrogen flow via supply ducts 10, 12, 14 into the furnace 100, respectively. A mass flow controller (MFC) 40 and air valve 30 to control and stop the flow of the gases through the supply ducts and supplied to the furnace.

The gas flow passing through the MFC 40 and air valve 30 is introduced through the burner 50 and then through supply duct 60 into the furnace 100. Oxygen and nitrogen passing through the respective air valve 30 are combined together at the duct 20 and introduced to the burner 50, while hydrogen is separately introduced via the duct 22 into the burner 50 and then into the furnace 100.

Silicon wafers or substrates held in the container 80 are loaded into the furnace 100, into which nitrogen gas flows via the duct 10. The temperature inside the furnace 100 is substantially maintained at about 600° C.-650° C. The temperature is maintained by using a heater for about 5 minutes (‘stabilization’) while continuing the nitrogen gas supply.

Then, the oxygen gas is introduced into the furnace 100 while raising the temperature inside the furnace to about 85° C.-1000° C. By introducing oxygen, the silicon surface on the wafers reacts with the oxygen to form an initial oxide layer on the wafers. When the temperature reaches a predetermined point, stabilization is carried out. The predetermined temperature point varies depending on the oxidation conditions and ranges from about 850° C. to about 1000° C. Stabilization is performed, followed by wet oxidation, which is performed by flowing hydrogen and oxygen, simultaneously to allow the oxide layer growing. The oxygen and hydrogen react chemically in the burner 50 and flow into the furnace 100 in the form of steam.

After the completion of wet oxidation, the final stabilization is carried out by flowing nitrogen gas only. Then, the temperature is lowered and the wafers are unloaded from the furnace 100.

The furnace currently employed for the wet oxidation has a burner where oxygen and hydrogen react at an elevated temperature to generate steam, which is introduced into the furnace during the wet oxidation process.

Since the wet oxidation using steam generated from a pyrogenic mixture of hydrogen and oxygen generates an unfavorably rapid growing of an oxide layer, it is difficult to control the thickness and quality of the oxide layer. To solve this problem, an inert gas may be used as a carrier for the oxygen. However, for this case, an inert gas inhibits the reaction of the oxygen and hydrogen in the burner so that a sufficient amount of pyrogenic steam cannot be generated, resulting in a poor wet oxidation.

Moreover, for the wet oxidation of wafer with a larger diameter, the insufficient partial pressure of the steam will cause a less uniform oxide layer.

### SUMMARY OF THE INVENTION

Thus, an object of the present invention is to remove the difficulty in obtaining a desired thickness and uniform oxide layer.

The present invention is to provide a wet oxidation process which allows a formation of a desired thickness and uniform oxide layer.

Generally, this invention provides that an inert gas is introduced into the furnace during one or more stages of the oxide layer forming process. That is, while this invention is described in terms of specific steps, the addition of an inert gas during any one stage in the process is within the scope of this invention. A furnace configured to provide the inert gas during the process is further within the scope of this invention.

More specifically, according to the present invention, a process for forming a thin oxide layer on a wafer includes the steps of:

loading a wafer into a furnace while flowing a first inert gas and a second inert gas over the wafer, the inert gases being selected from the group including of nitrogen, argon, helium, or any combination these inert or other gases (‘wafer load’);

maintaining a predetermined first temperature inside the furnace while flowing a first gas mixture including the first inert gas and oxygen, and the second inert gas over the wafer (‘first stabilization’);

raising the temperature to a predetermined second temperature while flowing a second gas mixture including the first inert gas and oxygen, and the second inert gas over the wafer (‘temperature ramp’);

maintaining the second temperature while flowing a third gas mixture including the first inert gas and oxygen, and the second inert gas over the wafer (‘second stabilization’);

performing a wet oxidation by using a fourth gas mixture including pyrogenic steam to form the oxide layer while flowing the second inert gas over the wafer (‘wet oxidation’); and

maintaining the temperature while flowing the first inert gas and the second inert gas over the wafer (‘third stabilization’).

According to the present invention, a process for forming a thin oxide layer on a semiconductor substrate including the steps of:

maintaining a predetermined first temperature inside a furnace while flowing a first gas mixture including a first inert gas and oxygen, and a second inert gas over the wafer, the first and second inert gases being selected from these or other groups including nitrogen, argon, helium, and any combination of inert gases (‘first stabilization’);

raising the temperature to a predetermined second temperature while flowing a second gas mixture including the first inert gas and oxygen, and the second inert gas over the wafer (‘temperature ramp’);

maintaining the second temperature while flowing a third gas mixture including the first inert gas and oxygen, and the second inert gas over the wafer (‘second stabilization’);

performing a wet oxidation by using a fourth gas mixture including pyrogenic steam to form the oxide layer while flowing the second inert gas over the wafer (‘wet oxidation’); and

maintaining the temperature while flowing the first inert gas and the second inert gas over the wafer (‘third stabilization’).

### BRIEF DESCRIPTION OF THE DRAWINGS

These and various other features and advantages of the present invention will be readily understood with reference to the following detailed description taken in conjunction with the accompanying drawings, such that like reference numerals designate like structural elements, and, in which:

FIG. 1 is a schematic diagram of the furnace used for the conventional wet oxidation process;

FIG. 2 is a graph showing the kind of gases and the range of the temperature employed for the conventional wet oxidation process in relation with the lapse of time;

FIG. 3 is a schematic diagram depicting a duct line for supplying gases to the furnace employed in the present invention;

FIG. 4 is a process flow diagram depicting the oxide layer formation process using an inert gas as a carrier during the wet oxidation according to the present invention;

FIG. 5 is a graph showing the kinds of gases and the range of the temperature employed for the wet oxidation process in relation with the lapse of time according to the present invention; and

FIG. 6 and FIG. 7 are graphs depicting the results of the wet oxidation according to the present invention.

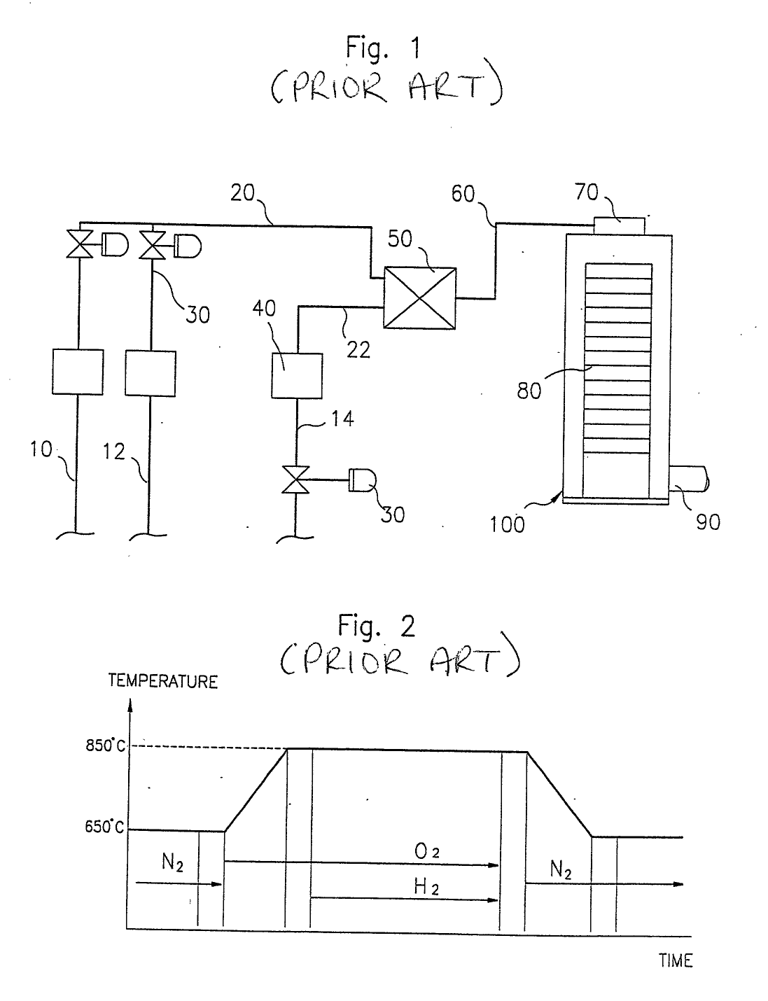

### DETAILED DESCRIPTION OF THE INVENTION

According to the present invention, the below described process for forming an oxide layer which allows easy control of the growth rate of oxide layer and a formation of a uniform oxide layer. Thus, the quality of the oxide layer is significantly improved. Further, the thickness of the oxide layer can be easily controlled.

The process of the present invention may be suitable for the formation of an oxide layer having a thickness of up to about 500 Å.

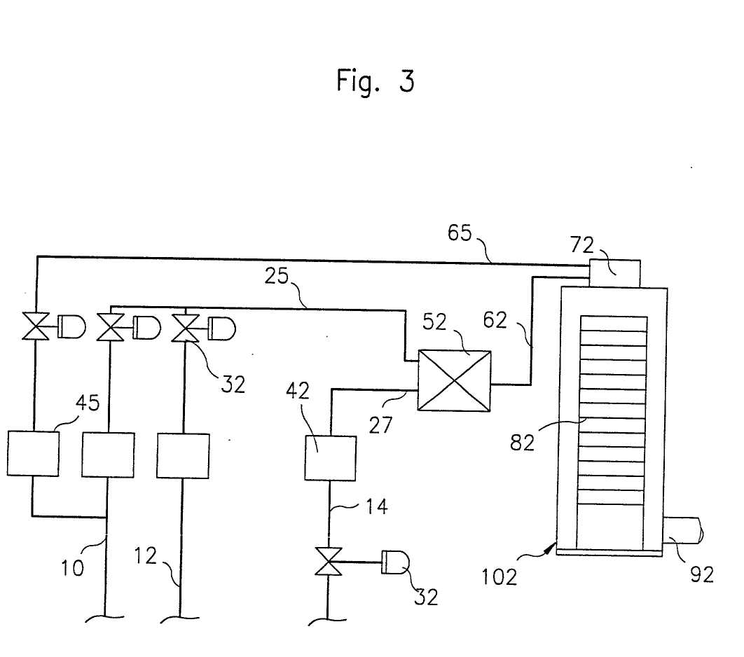

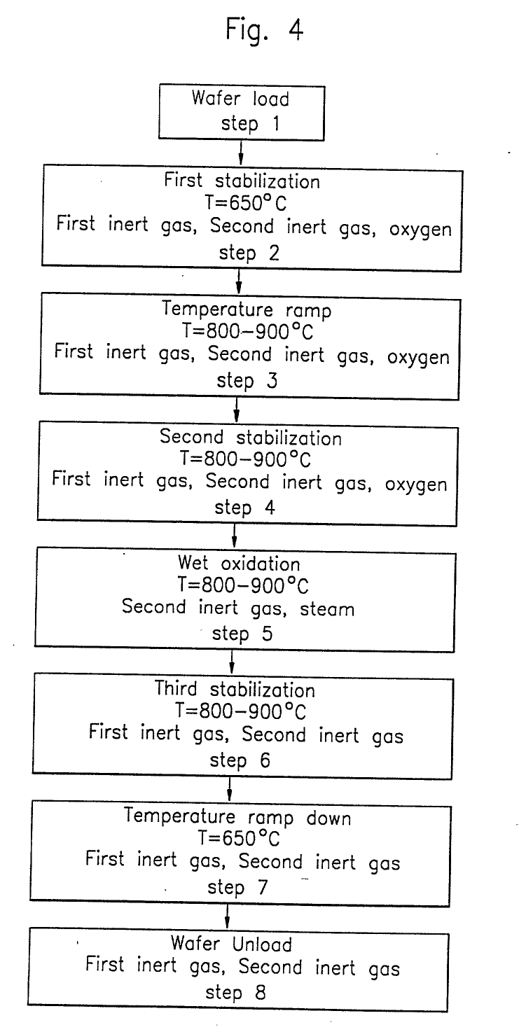

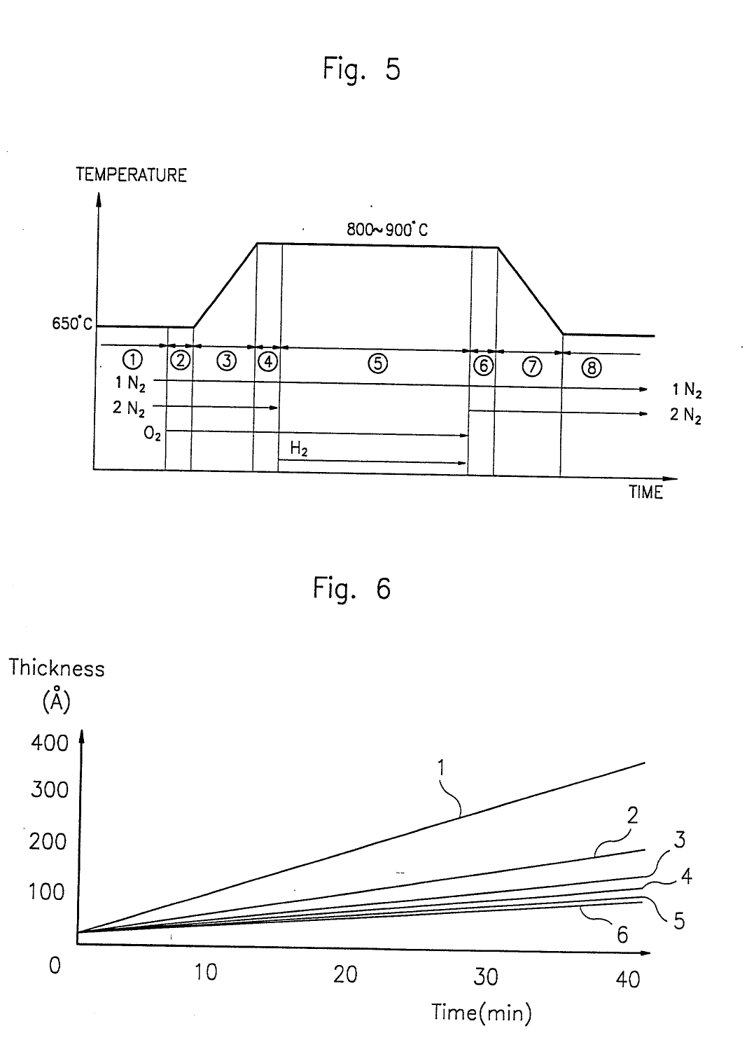

FIG. 3 is a schematic diagram depicting a duct line for supplying gases to the furnace employed in the present invention. FIG. 4 is a process flow diagram depicting the oxide layer formation process using an inert gas as a carrier during the wet oxidation according to the present invention. FIG. 5 is a graph depicting the kind of gases and the range of the temperature employed for the wet oxidation process in relation with the lapse of time according to the present invention.

Referring to FIG. 3, a first inert gas 10 and oxygen 12 are supplied via respective ducts and then via a single duct 25 to the burner 52. The ducts are provided with the MFC 42 to control the flow of the gases and air valves 32 to turn off or on the gas flows. Additionally, hydrogen 14 is separately supplied to the burner 52 via the separate duct 27. The inert gas 10 duct has a branch duct 65. The branch duct 65 is provided with its own MFC 45 and is connected to the head 72 of the furnace 102, not to the burner 52. That is to say, the inert gas flow passing the MFC 45 does not enter the burner 52. The inert gas passing through the burner 52 is referred to as the ‘first inert gas’, and the one bypassing the burner 52 and being introduced directly to the furnace 102 is referred to as the ‘second inert gas’. The first and second inert gas are selected from the group including of nitrogen, argon, helium or any combination of those gases. In FIGS. 3, the inert gas is represented by N₂.

According to the feature of the present invention, the second inert gas is introduced into the furnace throughout the whole process including during wet oxidation via a separate duct from the oxidizing agent introducing duct.

For the process of the present invention, first, wafers to be subjected to oxidation are loaded into the furnace 102 (‘Wafer load’; Step 1). Following step 1 is a first stabilization step (Step 2). During this step, the temperature is kept constant at approximately 650° C. for about 5 minutes to about 7 minutes, while a small amount of oxygen in the first inert gas (pure nitrogen) flows through the furnace 102. In more detail, a first gas mixture including 5 L/min-10 L/min of the first inert gas and about 500 mL/min of oxygen flow through the duct 62, and 5 L/min-10 L/min of the second inert gas flow through the duct 65. The proportion of oxygen with respect to the total volume of the first inert gas flow plus the second inert gas may be in a range of about 2.5-5% by volume.

After the first stabilization step, temperature ramp step (Step 3) follows, in which the temperature inside the furnace 102 is raised by heating a heater coil. During this step, the temperature is raised to about 800° C. to 900° C., while a second gas mixture and the second inert gas flow via the duct 62 and 65, respectively into and through the furnace 102. The second gas mixture has the same composition as that used in the first stabilization step. The temperature ramp step takes about 20 minutes to about 30 minutes.

During the temperature ramp step, the wafer surface reacts with oxygen in nitrogen to form an oxide layer having a thickness of about 5 Å to 30 Å. The pressure inside the furnace is kept at normal or ambient pressure.

After the temperature ramp step, a second stabilization step (Step 4) follows to maintain a constant temperature while a third gas mixture and the second inert gas flow via the duct 62 and 65, respectively into and through the furnace 102. The third gas mixture has the same composition as that used in the first stabilization step. This step takes about 7 minutes to about 9 minutes.

The second stabilization step is performed in order to accomplish and maintain the uniform temperature distribution throughout the inside of the furnace. Thus, the elevated temperature attained by the temperature ramp step is maintained by the second stabilization step. Had the subsequent wet oxidation been performed under an unstable and heterogeneous temperature distribution, the growth rate and quality of the oxide layer on the wafer could not be controlled.

After the second stabilization step, the wet oxidation (Step 5) is performed. The wet oxidation step includes a first burn and second burn. In the first burn step, the flow of the first inert gas passing the burner 52 in FIG. 3 stops, while the second inert gas of about 5 L/min-about 10 L/min flows through the duct 65 into the furnace 102 and oxygen of about 3 L/min flows through the duct 62 into the furnace 102. The first burn step is carried out for about 1 minute to about 2 minutes, and allows the oxide layer to grow as a result of the increased oxygen partial pressure present inside the furnace 102.

In the second burn step, about 3 L/min of hydrogen flows through the burner 52 into the furnace 102 under the same or similar conditions as those of the first burn step. The hydrogen is mixed and reacts with oxygen and the heat generated by burner 52 create a pyrogenic steam. The second burn step is carried out for about 1 minute to generate initial steam for forming the initial wet oxide layer.

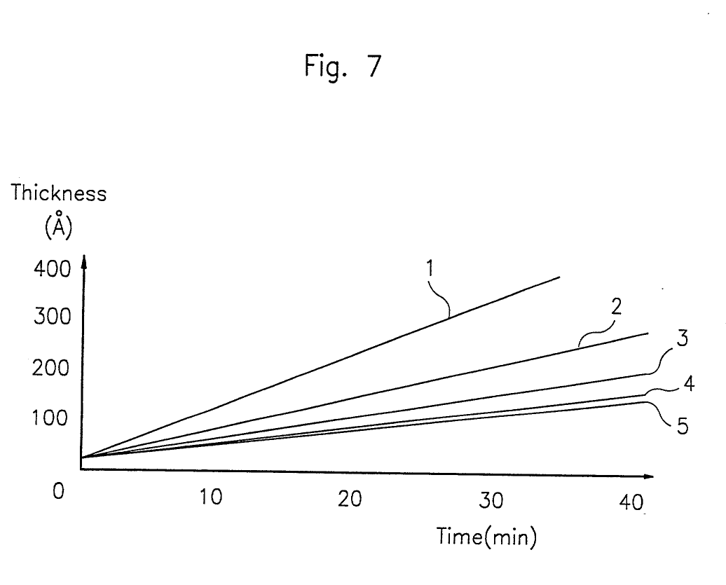

In turn, the wet oxidation step continues for about 20 minutes to about 30 minutes at a constant temperature. The volume of the second inert gas flow has a wide range and is determined depending on the wet oxidation temperature and time, the desired thickness of the oxide layer, and the like. For example, those of ordinary skill in the art can easily determine the volume of the second inert gas flow in order to form a desired thickness and uniform oxide layer with reference to the experimental or simulated data obtained by varying the wet oxidation temperature and the second inert gas flow volume as those in Table 1 given below or in FIGS. 6 and 7. In a specific embodiment, about 2.5-10 L/min of the second inert gas, and a gas mixture including a pyrogenic steam generated by chemical reaction of about 2-5 L/min of oxygen and about 3-7.5 L/min of hydrogen in the burner 52 flow via duct 65 and duct 62, respectively, into the furnace 102. At this time, the first inert gas does not flow into the burner 52, and therefore does not disturb the reaction of oxygen and hydrogen. The steam from the burner 52 and the second inert gas combine together in the head 70 and flow into the furnace 102. The second inert gas does not participate in the oxide formation. Rather, it has a role of maintaining a constant partial pressure inside the furnace and of slowing down the growth rate of the oxide layer so that the thickness of the oxide layer can be easily controlled.

The theoretical background of the inert gas dilution for wet oxidation can be explained below:

Among other theories for explaining the high temperature oxidation of silicon, DEAL-GROVB describes it as follows:

Stage 1: Adhesion of vapor oxidizing agent (steam or oxygen) onto the surface of oxide layer.

Stage 2: Diffusion migration of oxide.

Stage 3: Growing of oxide on the interface between the silicon and oxide layer by reaction.

In stage 1, the adhesion of the oxidizing agent on the surface of the oxide layer follows the Henry's rule, and therefore is proportional to the partial pressure of the oxidizing agent inside the furnace. Thus, the second inert gas flows into the furnace so as to reduce the partial pressure of the oxidizing agent during the wet oxidation. To reduce the partial pressure of the oxidizing agent, the amount of oxidizing agent flow may be reduced. But, this approach is not advantageous in that the reduced flow, and therefore, decreased diffusion rate of the oxidizing agent unduly increases the time for attaining an appropriate atmosphere for performing wet oxidation. The unduly increased oxidation time causes a heterogeneous distribution of oxide within the wafer as well as between the wafers.

If inert gas is supplied to compensate for the scant oxidizing agent, the inert gas serves as a carrier which improves the diffusion rate of oxidizing agent within a wafer and between wafers, and allows an uniform adhesion of the vapor oxidizing agent on the wafer. Moreover, the inert gas decreases the partial pressure of the oxidizing agent and therefore the concentration of the agent adhered to the surface of the oxide layer, resulting in a decrease in the growth rate of oxide layer. This makes it possible to form an uniform oxide layer in one wafer as well as between respective individual wafers.

That is to say, the process of the present invention allows an easy control of the thickness of the oxide layer on the wafer; a formation of uniform oxide layer; and an improvement of the quality of the oxide layer.

After the wet oxidation step, a third stabilization step (Step 6) follows while the first inert gas and the second inert gas flow into the furnace. The third stabilization step is to stabilize the wet oxide layer grown on the wafer and is carried out at the same or similar temperature as that of the wet oxidation step for about 10 minutes.

During the third stabilization step, about 10 L/min of first inert gas and about 5 L/min of second inert gas flow into the furnace.

Then, a temperature ramp down step (Step 7) follows to lower the temperature to about 650° C. for a period of about 40-60 minutes. After the temperature ramp down step, an unloading step (Step 8) is carried out to unload the wafer having an oxide layer from the furnace. During the temperature ramp down and the unloading steps, the first inert gas and the second inert gas flow into the furnace in same amounts as those of the third stabilization step.

FIG. 6 and FIG. 7 are graphs depicting the results of the wet oxidation (step 5) depending on the temperature of the wet oxidation step while varying the flow of the second inert gas. These graphs show the thickness of the oxide layer depending on the oxidation time. The initial oxide layer thickness is 25 Å, which is the thickness of the oxide layer grown in the temperature ramp step.

In FIG. 6 and FIG. 7, the line 1 indicates the conventional process wherein the second inert gas is not used, while the lines 2, 3, 4 and 5 indicate the wet oxidation according to the present invention. The lines 2, 3, 4 and 5 show the oxide growth rate when about 5 L/min, about 10 L/min, about 12.5 L/min and about 15 L/min of the second inert gas flows into the furnace, respectively. These graphs show that the growth rate becomes lower as the portion of the second inert gas increases.

FIG. 6 depicts the results of the wet oxidation at 820° C., and FIG. 7 depicts the wet oxidation at 850° C. The results of the wet oxidation at 900° C., which are in conformity with the results in FIGS. 6 and 7, are omitted. The results in FIGS. 6 and 7 are summarized in Table 1.

TABLE 1

| Temp. | | | |
|---|---|---|---|
| Gas ratio* | 820° C. | 850° C. | 900° C. |
| 0:6:9** | 8.99 Å/min*** | 14.58 Å/min | 28.78 Å/min |
| 5:2:3 | 4.60 Å/min | 7.37 Å/min | 14.59 Å/min |
| 10:2:3 | 2.92 Å/min | 4.97 Å/min | 10.01 Å/min |
| 15:2:3 | 2.27 Å/min | 3.84 Å/min | 7.80 Å/min |

*The gas ratio is based on the volume per minute, and represents the second inert gas (pure nitrogen):oxygen:hydrogen.
**Conventional
***Growth rate of oxide layer per minute

Table 1 shows the growth rate of wet oxide layer depending on the temperature of the wet oxidation step while varying the flow of the second inert gas.

When the wet oxidation is performed at a temperature of 820° C., which has been currently employed, without flowing the second inert gas, the oxide grows at a rate of about 14.58 Å per minute (Conventional process).

By contrast, for the present invention, when the wet oxidation is performed at 850° C., the growth rate varies between 3.84 Å/min and 7.37 Å/min depending on the volume of the second inert gas flow, and thus the present invention allows a control of the growth rate over a wide range of possible growth rates.

Referring to FIG. 7, it required about 6 minutes to obtain an oxide layer having about 100 Å thickness according to the conventional wet oxidation. By contrast, the wet oxidation of the present invention requires about 15 minutes to obtain about IOOA oxide layer when 10 L/min of the second inert gas flows into the furnace. This means that the time required for growing an oxide layer having a desired thickness can be easily controlled. To obtain a high quality thin oxide layer requires a sufficiently long growth time and oxidation time. Moreover, the stabilization of the oxidation temperature to 800-900° C. also has a significant effect on the quality of the oxide layer. Accordingly, the increase in the growth time of wet oxide layer means that the quality of the oxide layer can significantly improved.

Although preferred embodiments of the present invention have been described in detail above, it should be clearly understood that many variations and/or modifications of the basic inventive concepts herein taught which may appear to those skilled in the art will still fall within the spirit and scope of the present invention as defined in the appended claims.

What is claimed is:

1. A process for forming a thin oxide layer on a semiconductor wafer comprising the steps of:
at least one predetermined time, flowing a gas mixture including an inert gas inside a furnace configured to contain a subject wafer; and
performing a wet oxidation by using a gas mixture including a pyrogenic steam to form said oxide layer over said subject wafer.

2. A process as recited in claim 1 wherein during said flowing step, said gas mixture includes oxygen.

3. A process as recited in claim 1 wherein said performing a wet oxidation step occurs while flowing inert gas over said wafer.

4. A process as recited in claim 1, wherein said at least one predetermined time is a first time, wherein during said first time the temperature inside said furnace is maintained at a first predetermined temperature.

5. A process as recited in claim 4 wherein said at least one predetermined time is a second time, wherein during said second time the temperature inside said furnace is changed to a second predetermined temperature.

6. A process as recited in claim 5, wherein said changed temperature is a raised temperature.

7. A process as recited in claim 5 wherein said at least one predetermined time is a third time, wherein during said third time the temperature is maintained at said second predetermined temperature.

8. A process as recited in claim 7, wherein during said third time, two inert gases flow over said subject wafer.

9. A process as recited in claim 8, wherein after said performing a wet oxidation step, said furnace is maintained a third predetermined temperature.

10. A process as recited in claim 1 wherein said inert gas is selected from the group of inert gases comprising nitrogen, argon, helium, and any combination thereof.

11. A furnace configured to form a thin oxide layer on a semiconductor wafer comprising the steps of:
means for providing at least one predetermined time, a flow of a gas mixture including an inert gas inside said furnace configured to contain a subject wafer; and
means performing a wet oxidation by using a gas mixture including a pyrogenic steam to form said oxide layer over said subject wafer.

12. A furnace as recited in claim 11 wherein said inert gas is selected from the group of inert gases comprising nitrogen, argon, helium, and any combination thereof.

13. A furnace as recited in claim 12 wherein each one of said inert gas is provided to said furnace via said inert gases' own duct.

14. A furnace configured to form a thin oxide layer on a semiconductor wafer comprising the steps of:
ducts configured to, at least one predetermined time, provide a flow of a gas mixture including an inert gas inside said furnace configured to contain a subject wafer; and
ducts configured to provide a flow of material to perform wet oxidation by using a gas mixture including a pyrogenic steam to form said oxide layer over said subject wafer.

15. A process as recited in claim 14 wherein said inert gas is selected from the group of inert gases comprising nitrogen, argon, helium, and any combination thereof.

16. A furnace as recited in claim 15 wherein each one of said inert gas is provided to said furnace via said inert gases' own duct.

17. A process for forming a thin oxide layer on a semiconductor wafer comprising the steps of:
maintaining a predetermined first temperature inside a furnace while flowing a first gas mixture comprising a first inert gas and oxygen, and a second inert gas over said wafer, said first and second inert gases being selected from the group consisting of nitrogen, argon, helium, and any combination thereof (‘first stabilization’);
raising the temperature to a predetermined second temperature while flowing a second gas mixture comprising said first inert gas and oxygen, and said second inert gas over said wafer (‘temperature ramp’);
maintaining said second temperature while flowing a third gas mixture comprising said first inert gas and oxygen, and said second inert gas over said wafer (‘second stabilization’);
performing a wet oxidation by using a fourth gas mixture comprising a pyrogenic steam to form said oxide layer while flowing said second inert gas over said wafer (‘wet oxidation’); and
maintaining the temperature while flowing said first inert gas and said second inert gas over said wafer (‘third stabilization’).

18. A process according to claim 17, wherein said first inert gas and said second inert gas flow via separate ducts into the furnace.

19. A process according to claim 17, wherein, for said first stabilization step and said temperature ramp step, a volume ratio of said first inert gas flow and said second inert gas flow is approximately 1:1.

20. A process according to claim 17, wherein said wet oxidation step comprises the steps of:
performing a first burn step by flowing said second inert gas and oxygen over said wafer; and
performing a second burn step by flowing a gas mixture comprising said pyrogenic steam generated from a reaction of oxygen and hydrogen, and said second inert gas over said wafer.

21. A process according to claim 20, wherein said first burn step is performed for about 1 minute to about 2 minutes.

22. A process according to claim 20, wherein said second burn step is performed for about 1 minute.

23. A process according to claim 17, wherein said wet oxidation step is performed at a temperature of about 800° C. to about 900° C.

24. A process according to claim 17, which is suitable for forming an oxide layer having a thickness up to about 500 Å.

25. A process for forming a thin oxide layer on a semiconductor wafer comprising the steps of:
loading said wafer into a furnace while flowing a first gas mixture comprising a first inert gas and a second inert gas over said wafer, said inert gases being selected from the group consisting of nitrogen, argon, helium, or any combination thereof (‘wafer load’);
maintaining a predetermined first temperature inside said furnace while flowing a second gas mixture comprising said first inert gas and oxygen, and said second inert gas over said wafer (‘first stabilization’);
raising the temperature to a predetermined second temperature while flowing a third gas mixture comprising said first inert gas and oxygen, and said second inert gas over said wafer (‘temperature ramp’);
maintaining said second temperature while flowing a fourth gas mixture comprising said first inert gas and oxygen, and said second inert gas over said wafer (‘second stabilization’);
performing a wet oxidation by using a fifth gas mixture comprising pyrogenic steam to form said oxide layer while flowing said second inert gas over said wafer (‘wet oxidation’); and
maintaining the temperature while flowing said first inert gas and said second inert gas over said wafer (‘third stabilization’).

26. A process according to claim 25, wherein said first inert gas and said second inert gas flow via separate ducts into the furnace.

27. A process according to claim 25, wherein, for said first stabilization step and said temperature ramp step, a volume ratio of said first inert gas flow and said second inert gas flow is approximately 1:1.

28. A process according to claim 25, wherein said wet oxidation step comprises the steps of:
performing a first burn step by flowing said second inert gas and oxygen over said wafer; and
performing a second burn step by flowing a gas mixture comprising said pyrogenic steam generated from a reaction of oxygen and hydrogen, and said second inert gas over said wafer.

29. A process according to claim 28, wherein said first burn step is performed for about 1 minute to about 2 minutes.

30. A process according to claim 28, wherein said second burn step is performed for about 1 minute.

31. A process according to claim 25, wherein said wet oxidation step is performed at a temperature of about 800° C. to about 900° C.

32. A process according to claim 25, which is suitable for forming an oxide layer having a thickness up to about 500 Å.
